(19) United States
(12) Patent Application Publication
(10) Pub. No.: US 2008/0106442 A1
(43) Pub. Date: May 8, 2008

(54) Electronic apparatus with variable functional keys

(75) Inventor: Chi-Tong Lai, Tao Yuan City (TW)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Quanta Computer Inc.

(21) Appl. No.: 11/804,554

(22) Filed: May 17, 2007

(30) Foreign Application Priority Data
Nov. 3, 2006 (TW) 095140865

(51) Int. Cl. H03K 17/94

(52) U.S. Cl. 341/22

(57) ABSTRACT

The invention relates to an electronic apparatus including N functional keys, M functional modules, a communication module, and a processing module. Each of the M functional modules is in charge of a specific function. N is a natural number, and M is an integer larger than N. The communication module is capable of linking through a communication network to a server where N pre-defined definitions are stored. Each of the N pre-defined definitions corresponds to one of the N functional keys and indicates one of the M functional modules. The processing module is responsive to the key-in action of one of the functional keys and downloads the corresponding definition from the server through the communication module and the communication network, and drives one of the functional modules to perform the function charged by the functional module based on the downloaded corresponding definition.

### BACKGROUND OF THE INVENTION

1. Field of the Invention

The invention relates to an electronic apparatus with variable functional keys. Particularly, the electronic apparatus according to the invention is capable of downloading definitions from a server through a communication module and a communication network so as to drive a functional module to perform the function charged by the functional module.

2. Description of the Prior Art

With the development of communication technologies, nowadays, there have been various conventional communication functions, for example, short message service function, multimedia message service function, instant message service function, electronic mail function, voice call function, video call function, and phonebook function. And, the electronic apparatuses which can provide various communication functions have been developed into different kinds of apparatuses, for example, personal computers, notebooks, mobile phones, PDAs, intellectual phones, tablet computers, and information appliances.

However, most of the present small electronic apparatuses only have definite keys. Without good input/output equipment, if users want to change or select functional keys to fit their own needs, the change must be done via other input/output equipment by themselves or a professional.

Therefore, the scope of the invention is to provide an electronic apparatus with variable functional keys to solve the above problems.

### SUMMARY OF THE INVENTION

The scope of the invention is to provide an electronic apparatus which is capable of downloading definitions from a server through a communication module and a communication network so as to drive a functional module to perform the function charged by the functional module.

According to a preferred embodiment, the electronic apparatus based on the invention includes N functional keys, M functional modules, a communication module, and a processing module. N is a natural number, and M is an integer larger than N. Each of the M functional modules is in charge of a specific function. The communication module is capable of linking through a communication network to a server where N pre-defined definitions are stored. Each of the N pre-defined definitions corresponds to one of the N functional keys and indicates one of the M functional modules. The processing module is electrically coupled to the functional keys, the functional modules and the communication module respectively. And the processing module is used for downloading, responsive to the key-in action of one of the functional keys, the corresponding definition from the server through the communication module and the communication network. Based on the downloaded corresponding definition, the processing module drives one of the functional modules to perform the function charged by this functional module.

The advantage and spirit of the invention may be further understood by the following recitations together with the appended drawings.

### BRIEF DESCRIPTION OF THE APPENDED DRAWINGS

FIG. 1 is a schematic diagram of the connection structure of electronic apparatus connecting server of a preferred embodiment according to the invention; and

FIG. 2 is a schematic diagram of the appearance of electronic apparatus of a preferred embodiment according to the invention.

### DETAILED DESCRIPTION OF THE INVENTION

The invention provides an electronic apparatus with variable functional keys. And particularly, the electronic apparatus according to the invention is capable of downloading definitions from a server through a communication module and a communication network so as to drive a functional module to perform the function charged by the functional module. With the recitations of the following preferred embodiment, the features, spirits, advantages, and operation easiness of the invention will be well described.

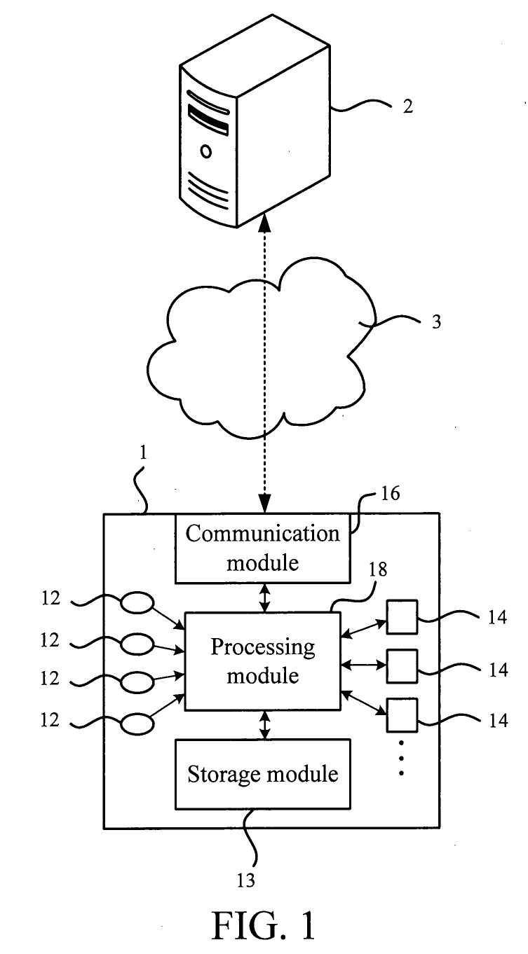

Referring to FIG. 1, FIG. 1 is a schematic diagram of the connection structure of an electronic apparatus 1 and a server 2 in a preferred embodiment according to the invention. As shown in FIG. 1, electronic apparatus 1 includes N functional keys 12, M functional modules 14, a communication module 16, and a processing module 18. N is a natural number, and M is an integer larger than N. Each of M functional modules 14 is in charge of a specific function.

As also shown in FIG. 1, communication module 16 is capable of linking through communication network 3 to server 2 where N pre-defined definitions are stored. Each of the N pre-defined definitions corresponds to one of the N functional keys 12 and indicates one of the M functional modules 14.

Processing module 18 is electrically coupled to functional keys 12, functional modules 14, and communication module 16 respectively. And processing module 18 downloads, responsive to the key-in action of one of functional keys 12, the corresponding definition from server 2 through communication module 16 and communication network 3. Based on the downloaded corresponding definition, processing module 18 drives one of functional modules 14 to perform the function charged by this functional module.

Moreover, in an embodiment, each of the pre-defined definitions includes a respective set of instructions and/or information. Processing module 18 drives, based on the downloaded corresponding definition, one of functional modules 14 to perform the function charged by this functional module in accordance with the instructions and/or information includes in the downloaded corresponding definition.

In addition, in order to permit users to update via communication module 16, communication network 3 can be a local area network, an intranet, an internet, a radio telecommunication network, or a public switched telephone network.

In an embodiment, electronic apparatus 1 further includes a storage module 13. Storage module 13 is electrically coupled to processing module 18, and N current definitions are stored in storage module 13. Each of the N current definitions corresponds to one of N functional keys 12 and indicates one of M functional modules 14. When communication module 16 malfunctions, processing module 18 accesses, responsive to key-in of one of functional keys 12, the corresponding definition from storage module 13, and based on the accessed corresponding definition, drives one of functional modules 14 to perform the function charged by this functional module.

In another embodiment, electronic apparatus 1 further includes storage module 13, storage module 13 is electrically coupled to processing module 18, and N current definitions are stored in storage module 13. Each of the N current definitions corresponds to one of N functional keys 12 and indicates one of M functional modules 14. Processing module 18 also downloads the corresponding definition from server 2 through communication module 16 and communication network 3, and updates the current definitions stored in storage module 13 by the downloaded definitions.

Besides, in an embodiment, the M functions charged by M functional modules 14 can include a browser function, a broadcaster function, an application program function, a virtual keyboard function, a short message service (SMS) function, a multimedia message service (MMS) function, an instant message service (IMS) function, an E-mail function, a voice call function, a video call function, or a phonebook function.

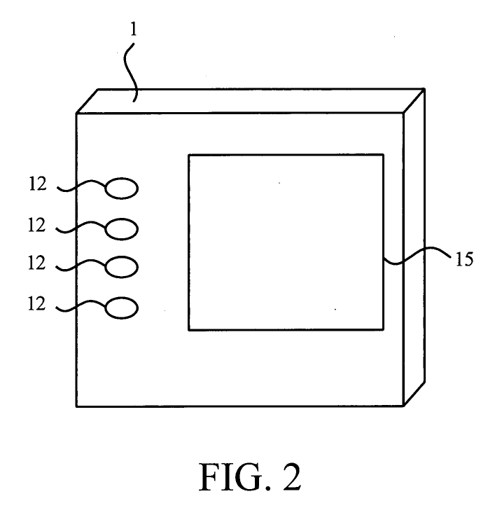

Referring to FIG. 2, FIG. 2 is an appearance diagram of electronic apparatus 1 in a preferred embodiment according to the invention. As shown in FIG. 2, for example, electronic apparatus 1 can be an electronic browser. After a user pushes functional key 12, many pre-defined functions, such as the top 5 picture on internet, the top 5 news on internet, certain chapter of an electronic book read yesterday, or today's lessons of certain course in school can be shown on monitor 15. Thus, even with only definite functional keys 12, a user can perform a lot of functions with complicated instructions. Besides, some users are not good at setting the functions of electronic apparatus 1, but users can easily select and perform the functions they want via electronic apparatus 1 with several simple functional keys 12 provided by the invention.

With the recitations of the preferred embodiment above, the features and spirits of the invention will be hopefully well described. However, the scope of the invention is not restricted by the preferred embodiment disclosed above. The objective is that all alternative and equivalent arrangements are hopefully covered in the scope of the appended claims of the invention. Accordingly, the above disclosure should be construed as limited only by the metes and bounds of the appended claims.

What is claimed is:

1. An electronic apparatus, comprising:
N functional keys, N being a natural number;
M functional modules, each of the M functional modules being in charge of a specific function, M being an integer larger than N;
a communication module capable of linking through a communication network to a server where N pre-defined definitions are stored, each of the N pre-defined definitions corresponding to one of the N functional keys and indicating one of the M functional modules; and
a processing module, electrically coupled to the functional keys, the functional modules, and the communication module respectively, responsive to the key-in action of one of the functional keys, the processing module downloading the corresponding definition from the server through the communication module and the communication network, and based on the downloaded corresponding definition, the processing module driving one of the functional modules to perform the function charged by the functional module.

2. The electronic apparatus of claim 1, wherein each of the pre-defined definitions comprises a respective set of instructions and/or information, and the processing module drives, based on the downloaded corresponding definition, one of the functional modules to perform the function charged by the functional module in accordance with the instructions and/or information comprised in the downloaded corresponding definition.

3. The electronic apparatus of claim 1, wherein the communication network is one selected from the group consisting of: a local area network, an intranet, an internet, a radio telecommunication network, and a public switched telephone network.

4. The electronic apparatus of claim 1, further comprising a storage module, electrically coupled to the processing module, therein storing N current definitions, each of the N current definitions corresponding to one of the N functional keys and indicating one of the M functional modules, wherein when the communication module malfunctions, the processing module accesses, responsive to the key-in action of one of the functional keys, the corresponding definition from the storage module, and based on the accessed corresponding definition, the processing module drives one of the functional modules to perform the function charged by the functional module.

5. The electronic apparatus of claim 1, further comprising a storage module, electrically coupled to the processing module, therein storing N current definitions, each of the N current definitions corresponding to one of the N functional keys and indicating one of the M functional modules, wherein the processing module also downloads the other definitions other than the corresponding definition from the server through the communication module and the communication network, and the processing module updates the current definitions stored in the storage module with the downloaded definitions.

6. The electronic apparatus of claim 1, wherein the M functions charged by the M functional modules comprise one selected from the group consisting of: a browser function, a broadcaster function, an application program function, a virtual keyboard function, a short message service (SMS) function, a multimedia message service (MMS) function, an instant message service (IMS) function, an E-mail function, a voice call function, a video call function, and a phonebook function.
